(19) United States
(12) Patent Application Publication
(10) Pub. No.: US 2025/0309154 A1
(43) Pub. Date: Oct. 2, 2025

(54) SEMICONDUCTOR DEVICE

(71) Applicant: Fujitsu Limited, Kawasaki-shi (JP)

(72) Inventors: Yusuke KUMAZAKI, Atsugi (JP); Shirou OZAKI, Yamato (JP); Toshihiro OHKI, Hadano (JP); Yasuhiro NAKASHA, Hadano (JP); Naoya OKAMOTO, Isehara (JP); Naoki HARA, Sagamihara (JP)

(73) Assignee: Fujitsu Limited, Kawasaki-shi (JP)

(21) Appl. No.: 19/049,037

(22) Filed: Feb. 10, 2025

(30) Foreign Application Priority Data
Mar. 28, 2024 (JP) 2024-052684

(51) Int. Cl. H01L 23/66; H01L 23/522; H01L 23/528; H10D 30/47

(52) U.S. Cl. CPC H01L 23/66; H01L 23/5228; H01L 23/5286; H01L 2223/6627; H10D 30/475

(57) ABSTRACT

A semiconductor device including: a semiconductor substrate; a coplanar type line that includes a signal line and a ground metal formed on a surface side of the semiconductor substrate; and a first resistive film formed between a surface of the semiconductor substrate and the ground metal or between a surface of the semiconductor substrate and a region where there is no metal over the semiconductor substrate, wherein the ground metal and the first resistive film are insulated from each other.

### CROSS-REFERENCE TO RELATED APPLICATION

This application is based upon and claims the benefit of priority of the prior Japanese Patent Application No. 2024-52684, filed on Mar. 28, 2024, the entire contents of which are incorporated herein by reference.

### FIELD

The embodiment discussed herein is related to a semiconductor device including a coplanar type line.

### BACKGROUND

In next-generation communication (beyond 5th generation (B5G)/6th generation (6G)), wireless communication using radio waves in a sub-terahertz (sub-THz) band such as a 100 GHz band and a 300 GHz band has been considered in order to achieve a transmission rate exceeding 100 Gbps. For example, development of 100 GHz band beam control and 300 GHz band 4×4 antenna modules is being advanced. As one of elemental techniques for achieving such wireless communication, a high-speed/high-power amplifier is desired.

For example, a high electron mobility transistor (HEMT) using a gallium nitride (GaN)-based material has a high breakdown voltage and is utilized as a high-power amplifier. An indium phosphide (InP)-based HEMT is excellent in high-speed operability and has low noise, and thus is suitable as an amplifier used in a frequency band of the sub-terahertz band.

In the sub-terahertz band, ¼ wavelength of a radio wave may be about the same as or smaller than a substrate thickness. For this reason, resonance due to propagation in a substrate may occur. For example, the thickness of a normal semiconductor substrate is 75 to 200 μm. In a silicon carbide (SiC) substrate (εr=9.66), ¼ wavelength of an electromagnetic wave that passes through the substrate is approximately 240 μm at 100 GHz and approximately 80 μm at 300 GHz. Propagation in a substrate may cause unstable operation of an amplifier and/or an increase in loss. In many cases, power added efficiency of an amplifier tends to decrease with an increase in frequency. For example, in the sub-terahertz band, the power added efficiency of an amplifier is about 10 percent. Since most of the input power is converted into heat, the amount of heat generation is large.

For example, a technique of reducing conduction noise is described in Japanese Laid-open Patent Publication No. 2009-038250. For example, a technique of improving high-frequency isolation characteristics between terminals coupled to a transmission line is described in Japanese Laid-open Patent Publication No. 2005-287055. For example, a technique of reducing unwanted radiation waves by forming a resistive film on the rear surface of a substrate is described in Japanese Laid-open Patent Publication No. 2007-165430.

Japanese Laid-open Patent Publication No. 2009-038250, Japanese Laid-open Patent Publication No. 2005-287055, and Japanese Laid-open Patent Publication No. 2007-165430 are disclosed as related art.

H. Hamada et al., “Millimeter-wave InP Device Technologies for Ultra-high Speed Wireless Communications toward Beyond 5G”, 2019 IEEE International Electron Devices Meeting (IEDM), San Francisco, CA, USA, 2019, pp. 9.2.1 to 9.2.4, doi: 10.1109/IEDM19573.2019.8993540 is disclosed as related art.

### SUMMARY

According to an aspect of the embodiments, there is provided a semiconductor device including: a semiconductor substrate; a coplanar type line that includes a signal line and a ground metal formed on a surface side of the semiconductor substrate; and a first resistive film formed between a surface of the semiconductor substrate and the ground metal or between a surface of the semiconductor substrate and a region where there is no metal over the semiconductor substrate, wherein the ground metal and the first resistive film are insulated from each other.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 (i.e., FIGS. 1A to 1C) is a diagram illustrating an example of a semiconductor device according to an embodiment of the present disclosure;

FIG. 2 is a diagram illustrating a simulation result of the pass characteristic in a coplanar type line illustrated in FIG. 1 (part 1);

FIG. 3 is a diagram illustrating a simulation result of the pass characteristic in the coplanar type line illustrated in FIG. 1 (part 2);

FIG. 4 is a diagram illustrating a simulation result of the pass characteristic in the coplanar type line illustrated in FIG. 1 (part 3);

FIG. 5 is a top view of a semiconductor device according to a first exemplary embodiment;

FIG. 6 (i.e., FIGS. 6A and 6B) is a cross-sectional view of the semiconductor device illustrated in FIG. 5;

FIG. 7 is a diagram illustrating an example of a method for manufacturing the semiconductor device according to the first exemplary embodiment (part 1);

FIG. 8 is a diagram illustrating an example of the method for manufacturing the semiconductor device according to the first exemplary embodiment (part 2);

FIG. 9 is a diagram illustrating an example of the method for manufacturing the semiconductor device according to the first exemplary embodiment (part 3);

FIG. 10 is a diagram illustrating an example of the method for manufacturing the semiconductor device according to the first exemplary embodiment (part 4);

FIG. 11 is a diagram illustrating an example of the method for manufacturing the semiconductor device according to the first exemplary embodiment (part 5);

FIG. 12 is a diagram illustrating an example of the method for manufacturing the semiconductor device according to the first exemplary embodiment (part 6);

FIG. 13 is a top view of a semiconductor device according to a second exemplary embodiment;

FIG. 14 (FIGS. 14A and 14B) is a cross-sectional view of the semiconductor device illustrated in FIG. 13;

FIG. 15 is a diagram illustrating an example of a method for manufacturing the semiconductor device according to the second exemplary embodiment (part 1);

FIG. 16 is a diagram illustrating an example of the method for manufacturing the semiconductor device according to the second exemplary embodiment (part 2);

FIG. 17 is a diagram illustrating an example of the method for manufacturing the semiconductor device according to the second exemplary embodiment (part 3);

FIG. 18 is a diagram illustrating an example of the method for manufacturing the semiconductor device according to the second exemplary embodiment (part 4);

FIG. 19 is a diagram illustrating an example of the method for manufacturing the semiconductor device according to the second exemplary embodiment (part 5); and

FIG. 20 is a diagram illustrating an example of communication equipment in which the semiconductor device according to the embodiment of the present disclosure is mounted.

### DESCRIPTION OF EMBODIMENTS

As an example of the related art, there is a configuration in which propagation in a substrate is reduced in the sub-terahertz band by thinning the substrate (for example, 50 μm or less). However, if the substrate is thinned, heat is less likely to be diffused in a lateral direction, and thus heat dissipation characteristics are degraded. Also in the configuration in which a resistive film is formed on the rear surface of a substrate, the heat dissipation characteristics are degraded.

An object according to an aspect of the present disclosure is to reduce unstable operation caused by propagation in a substrate in a high-speed semiconductor device.

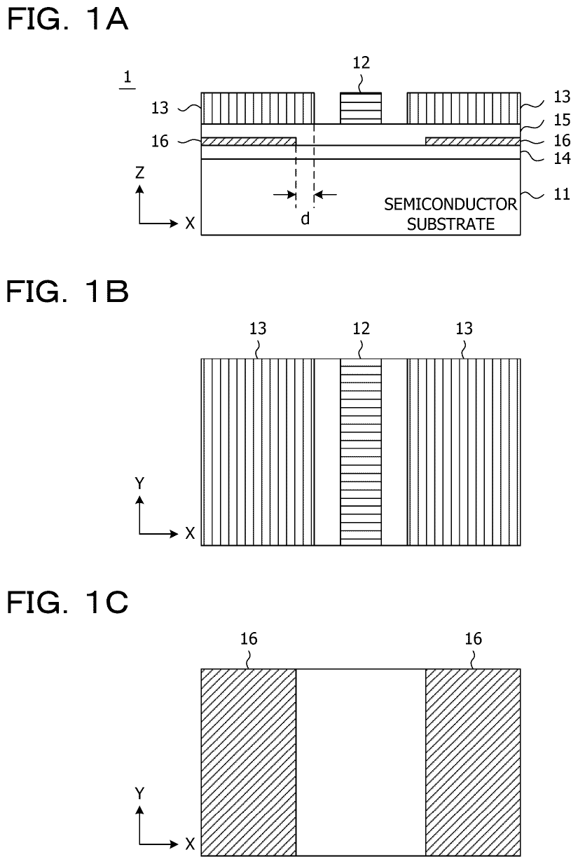

FIG. 1 (i.e., FIGS. 1A to 1C) illustrates an example of a semiconductor device according to an embodiment of the present disclosure. Although not particularly limited, for example, a semiconductor device 1 according to the embodiment of the present disclosure is a semiconductor amplifier. Note that FIG. 1 illustrates a transmission path portion coupled to a transistor constituting the amplifier.

As illustrated in FIG. 1A, the semiconductor device 1 is configured by using a semiconductor substrate 11. Although not particularly limited, for example, the semiconductor substrate 11 is a silicon carbide (SIC) substrate.

A metal film is selectively formed over the upper surface of the semiconductor substrate 11. The metal film constitutes a coplanar type line including a signal line 12 and a ground metal 13. A surface protection film 14 and an interlayer insulating film 15 are formed between the metal film (for example, the signal line 12 and the ground metal 13) and the semiconductor substrate 11. Although not particularly limited, for example, the surface protection film 14 and the interlayer insulating film 15 are silicon nitride (SiN).

A resistive film 16 is formed over the upper surface of the semiconductor substrate 11. In this exemplary embodiment, the resistive film 16 is formed over the upper surface of the surface protection film 14. The resistive film 16 is electrically insulated from the metal film (the signal line 12 and the ground metal 13) by the interlayer insulating film 15. The resistive film 16 is formed at a position where the resistive film does not substantially affect the characteristic impedance of the coplanar type line.

The resistive film 16 is preferably formed directly under the ground metal 13. The resistive film 16 may be formed directly under a region where no metal exists over the semiconductor substrate 11. Alternatively, the resistive film 16 may be formed both directly under the ground metal 13 and directly under the region where no metal exists over the semiconductor substrate 11. However, the resistive film 16 is not formed directly under the signal line 12. The resistive film 16 is not formed directly under the signal line 12 at least in a region where the signal line 12 acts as the coplanar type line. For example, in a case where the signal line 12 is coupled to the transistor in the semiconductor device, the resistive film 16 may be formed directly under the signal line 12 in a region where the transistor is formed.

In addition, the resistive film 16 is formed such that the edge of the resistive film 16 does not reach the edge of the ground metal 13 on the side facing the signal line 12. For example, in the X direction illustrated in FIG. 1A, the distance d between the edge of the resistive film 16 and the edge of the ground metal 13 on the side facing the signal line 12 is preferably 10 μm or longer. Although not particularly limited, for example, the distance d represents the distance between the edge of the resistive film 16 and the edge of the ground metal 13 on the side facing the signal line 12 when the semiconductor device 1 is viewed from above (for example, in a plan view). The sheet resistance of the resistive film 16 is preferably 10 ohms/square or larger.

The signal line 12 and the ground metal 13 constituting the coplanar type line are formed so as to extend in a direction perpendicular to the paper surface in FIG. 1A. For example, as illustrated in FIG. 1B, the signal line 12 and the ground metal 13 are formed so as to extend in the Y direction. The resistive film 16 is also formed so as to extend in the direction perpendicular to the paper surface in FIG. 1A. For example, as illustrated in FIG. 1C, the resistive film 16 is formed so as to extend in the Y direction.

A coplanar type line is configured by sandwiching a signal line between ground metals. Characteristic impedance of a coplanar type line is substantially determined by the width of a signal line, the distance between the signal line and a ground metal, and the surrounding effective dielectric constant. For example, characteristic impedance of a coplanar type line is hardly affected by the thickness of a substrate or the material provided on the rear surface of the substrate. Therefore, the thickness of the semiconductor substrate 11 may be made larger than the thickness of a normal substrate (for example, 100 μm) in order to increase thermal conductivity. SiC or diamond having high heat dissipation efficiency may be provided on the rear surface (for example, the surface on the opposite side of the surface over which the signal line 12 and the ground metal 13 are formed) of the semiconductor substrate 11. In a configuration in which a microstrip line is adopted, since the ground is provided on the rear surface of a substrate, the degree of freedom in designing the thickness of the substrate and/or the material to be provided on the rear surface of the substrate is small.

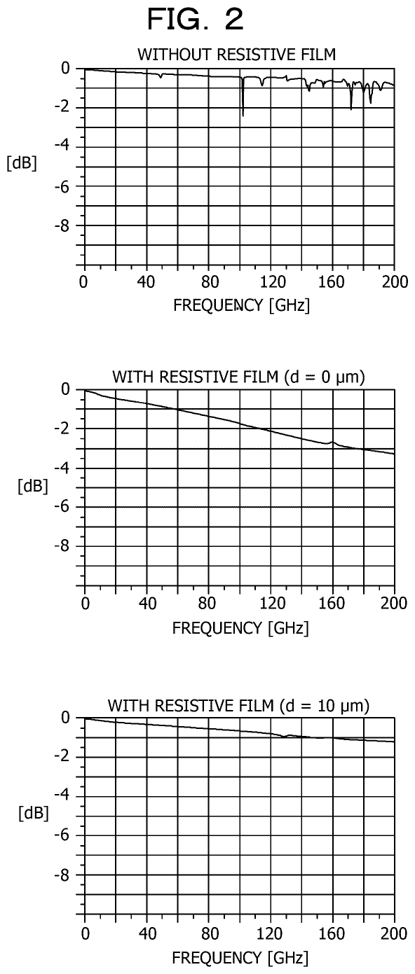

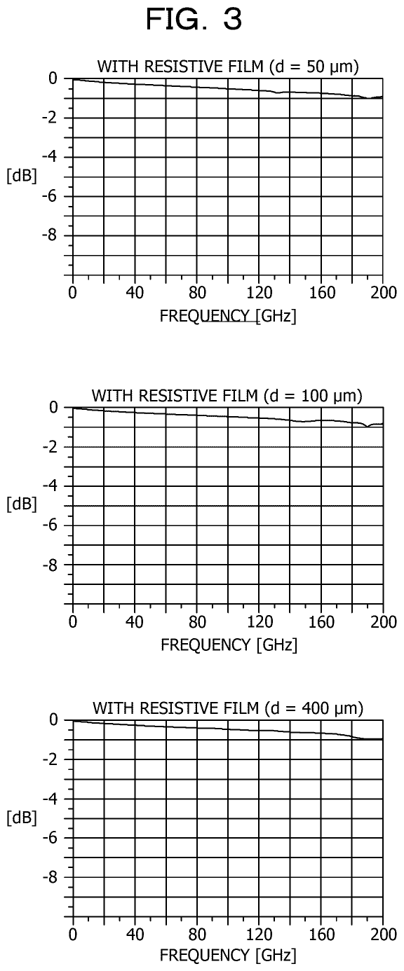

Next, with reference to FIGS. 2 and 3, the reason for providing the resistive film 16 and the disposition of the resistive film 16 will be described. FIGS. 2 and 3 illustrate simulation results of the pass characteristic in the coplanar type line illustrated in FIG. 1. The horizontal axis represents the frequency of a signal supplied to the signal line 12 of the semiconductor device 1. In this simulation, the semiconductor substrate 11 is an SiC substrate and has a thickness of 350 μm. The surface protection film 14 and the interlayer insulating film 15 are SiN layers. The width of the signal line 12 is 22 μm. The gap between the signal line 12 and the ground metal 13 is 14 μm. The characteristic impedance of the coplanar type line is 50 ohms. The sheet resistance of the resistive film 16 is 50 ohms/square. The length of the line (the length of the signal line 12 in the Y direction in FIG. 1) is 1 mm.

According to this simulation, in a case where the resistive film 16 is not provided, discontinuous behavior appears in the sub-terahertz band (100 GHz to 200 GHz in FIGS. 2 and 3). For example, the pass characteristic has a local minimum point at some frequencies. It is considered that the discontinuous behavior occurs due to resonance caused by propagation in the substrate. Due to the unstable operation, an increase in loss is concerned.

By contrast, when the resistive film 16 is provided, discontinuous behavior in the sub-terahertz band is reduced. For example, at 100 GHz to 200 GHz, the pass characteristic continuously changes without having a local minimum point. In the configuration including the resistive film 16, when an electromagnetic wave propagating in the substrate reaches the resistive film 16, a conduction current flows through the resistive film 16 and the energy of the electromagnetic wave is converted into heat. For example, the electromagnetic wave in the substrate is absorbed by the resistive film 16 without being reflected. Therefore, propagation in the substrate is reduced, and discontinuous behavior is reduced.

However, in the case where the resistive film 16 is formed directly under the ground metal 13, when the resistive film 16 is formed up to the edge of the ground metal 13 (the edge of the ground metal 13 on the side facing the signal line 12), the pass loss in the coplanar type line increases. This pass loss depends on the distance between the edge of the resistive film 16 and the edge of the ground metal 13 on the side facing the signal line 12 (for example, the distance d illustrated in FIG. 1A). For example, with respect to the distance d, the pass characteristic at 100 GHz changes as follows. 0 μm: −1.741 dB 10 μm: −0.660 dB 50 μm: −0.509 dB 100 μm: −0.481 dB 400 μm: −0.456 dB

As has been described, it is considered that a transmission signal is attenuated by the resistive film 16 when the distance d is small. Therefore, the distance d is preferably increased in order to improve the pass loss. For example, in order to reduce the pass loss to 1 dB or less, the distance d is preferably 10 μm or longer. However, according to this simulation, a change in pass loss is not large if the distance d is 10 μm or longer. If the distance d is increased, it is difficult to reduce the size of the semiconductor device 1. Therefore, an upper limit of the distance d is preferably determined in consideration of the size of the semiconductor device 1.

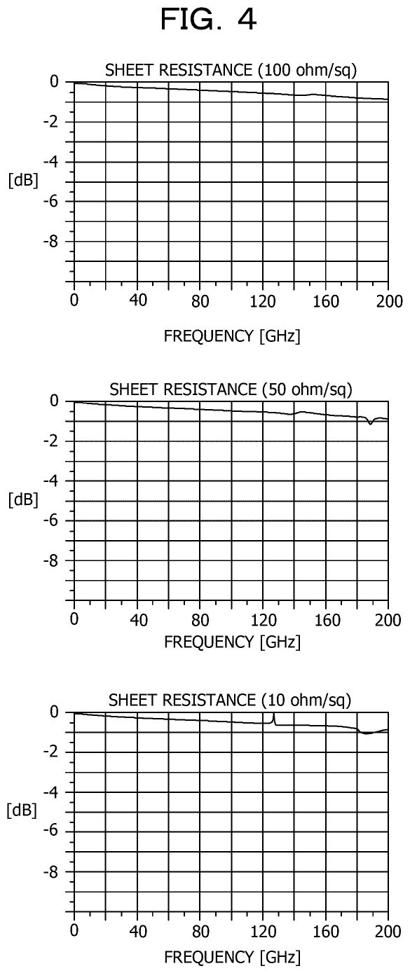

The pass characteristic of the coplanar type line depends on the resistance value (sheet resistance in this exemplary embodiment) of the resistive film 16. With reference to FIG. 4, the relationship between the sheet resistance of the resistive film 16 and the pass characteristic of the coplanar type line will be described below.

As with FIGS. 2 and 3, FIG. 4 illustrates a simulation result of the pass characteristic in the coplanar type line illustrated in FIG. 1. Simulation conditions in FIG. 4 are the same as those in FIGS. 2 and 3. However, in FIG. 4, the distance d is 100 μm.

According to this simulation, discontinuous behavior does not appear when the sheet resistance of the resistive film 16 is large (for example, 100 ohms/square). When the sheet resistance of the resistive film 16 is 50 ohms/square, discontinuous behavior (a local minimum point) appears at 180 to 200 GHz. When the sheet resistance of the resistive film 16 is 10 ohms/square, discontinuous behavior appears at 120 to 140 GHz. For example, as the sheet resistance of the resistive film 16 decreases, the frequency at which discontinuous behavior appears tends to decrease. When the sheet resistance of the resistive film 16 decreases, the metallic behavior increases. As a result, it is considered that the electromagnetic wave in the substrate is reflected without being attenuated by the resistive film 16 and discontinuous behavior appears.

Therefore, in order to reduce radio wave propagation in the substrate, the sheet resistance of the resistive film 16 is preferably made larger than a predetermined value. In this case, the sheet resistance of the resistive film 16 may be determined in consideration of the frequency of a signal supplied to the semiconductor device 1. For example, according to the simulation illustrated in FIG. 4, when the sheet resistance of the resistive film 16 is 10 ohms/square, discontinuous behavior appears at 120 to 140 GHz. For example, when a 100 GHz signal is applied to the semiconductor device 1, discontinuous behavior does not appear as long as the sheet resistance of the resistive film 16 is 10 ohms/square or larger. Therefore, in this case, the sheet resistance of the resistive film 16 is preferably 10 ohms/square or larger.

However, if the sheet resistance of the resistive film 16 is too large, a conduction current does not flow through the resistive film 16 when an electromagnetic wave propagating in the substrate reaches the resistive film 16, and the energy of the electromagnetic wave is not converted into heat. For example, there is a possibility that propagation in the substrate is not reduced. Therefore, the sheet resistance of the resistive film 16 is preferably determined so that the resistive film 16 does not act as an insulator.

### First Exemplary Embodiment

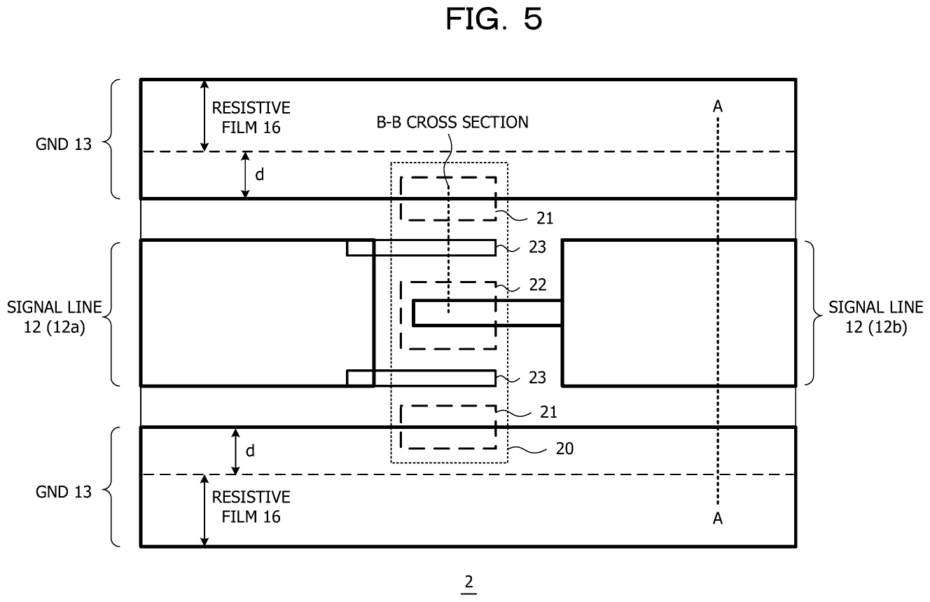

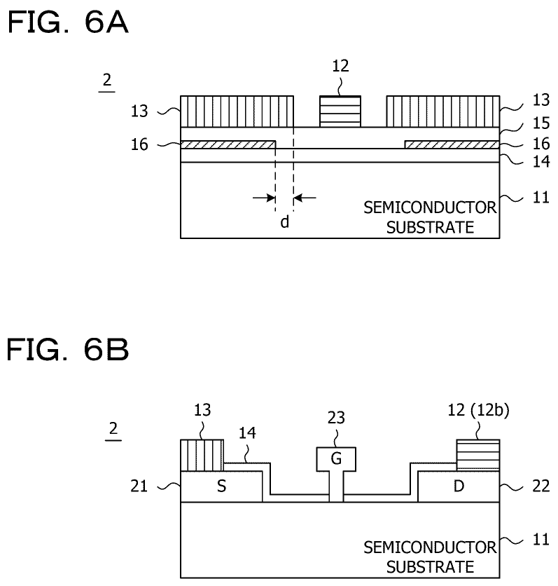

FIG. 5 and FIG. 6 (i.e., FIGS. 6A and 6B) illustrate a configuration of a semiconductor device 2 according to a first exemplary embodiment. FIG. 5 is a top view (plan view) of the semiconductor device 2 according to the first exemplary embodiment. FIG. 6A is a cross-sectional view taken along line A-A of the semiconductor device 2 illustrated in FIG. 5. FIG. 6B is a cross-sectional view taken along line B-B of the semiconductor device 2 illustrated in FIG. 5. The semiconductor device 2 includes a transistor that operates as an amplifier and a coplanar type line that is coupled to the amplifier. In FIG. 5, a transistor region 20 represents a region where the transistor that operates as an amplifier is formed.

As illustrated in FIG. 5 or FIG. 6B, the transistor includes a source electrode 21, a drain electrode 22, and a gate electrode 23. The coplanar type line is configured by the signal line 12 and the ground metal 13 described with reference to FIG. 1. In this exemplary embodiment, the signal line 12 includes a signal line 12a and a signal line 12b.

The source electrode 21 is formed over the upper surface of the semiconductor substrate 11. The source electrode 21 is provided between the ground metal 13 and the semiconductor substrate 11. The source electrode 21 is preferably in contact with (or electrically coupled to) the ground metal 13 and the semiconductor substrate 11. The drain electrode 22 is formed over the upper surface of the semiconductor substrate 11. The drain electrode 22 is provided between the signal line 12 (12b) and the semiconductor substrate 11. The drain electrode 22 is preferably in contact with (or electrically coupled to) the signal line 12 (12b) and the semiconductor substrate 11. The gate electrode 23 is formed over the upper surface of the semiconductor substrate 11 in a region between the source electrode 21 and the drain electrode 22. The gate electrode 23 is electrically coupled to the signal line 12 (12a).

In the semiconductor device 2 of the above configuration, for example, a predetermined power supply voltage is applied to the drain electrode 22. A signal is supplied to the gate electrode 23 through the signal line 12a. By doing so, an amplified signal is output through the signal line 12a. The surface protection film 14 is provided in the transistor region 20.

The configuration of the coplanar type line is as described with reference to FIG. 1. For example, as illustrated in FIG. 6A, a metal film (the signal line 12 and the ground metal 13) constituting the coplanar type line is formed over the upper surface of the semiconductor substrate 11. The resistive film 16 is formed directly under the ground metal 13. However, the resistive film 16 is not formed in a region up to the distance d from the edge of the ground metal 13 on the side facing the signal line 12. The distance d is preferably 10 μm or longer. The resistive film 16 is not formed directly under the signal line 12. The resistive film 16 is insulated from the signal line 12 and the ground metal 13 by the interlayer insulating film 15. The sheet resistance of the resistive film 16 is preferably 10 ohms/square or larger.

In the semiconductor device 2 of the above configuration, a radio wave in the semiconductor substrate 11 resulting from an input signal and/or an output signal is attenuated by the resistive film 16. Therefore, even when the thickness of the semiconductor substrate 11 is made larger than ¼ wavelength of the radio wave, radio wave propagation in the substrate is reduced. As a result, unstable behavior is reduced in the sub-terahertz region. In addition, since the thickness of the semiconductor substrate 11 may be increased, heat dissipation characteristics are improved.

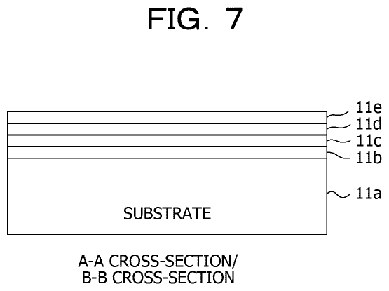

FIGS. 7 to 12 illustrate an example of a method for manufacturing the semiconductor device 2 according to the first exemplary embodiment. The semiconductor device 2 includes a gallium nitride (GaN)-based high electron mobility transistor (HEMT).

As illustrated in FIG. 7, the semiconductor substrate 11 is configured by forming an initial layer 11b, an electron transit layer 11c, a spacer layer 11d, and an electron supply layer 11e over a substrate 11a. For example, the initial layer 11b, the electron transit layer 11c, the spacer layer 11d, and the electron supply layer 11e are formed through epitaxial growth by metal organic chemical vapor deposition (MOCVD). For example, the substrate 11a is SiC, Si, sapphire, GaN, aluminum nitride (AlN), or diamond. For example, the initial layer 11b is formed of a nitride semiconductor such as AlN, GaN, aluminum gallium nitride (AlGaN), or a stacked structure thereof. For example, the electron transit layer 11c is formed of intrinsic gallium nitride (i-GaN). For example, the spacer layer 11d is formed of a nitride semiconductor such as AlN or AlGaN. For example, the electron supply layer 11e is formed of a nitride semiconductor such as AlGaN, indium aluminum nitride (InAlN), indium aluminum gallium nitride (InAlGaN), AlN, or scandium aluminum nitride (ScAlN). With this structure, in the electron transit layer 11c, two dimensional electron gas (2DEG) is generated in the vicinity of the interface between the electron transit layer 11c and the spacer layer 11d.

Next, an inactive region is formed by an element isolation process. With this, the transistor region 20 is defined. For example, a resist pattern including an opening in a region where an element isolation region is to be formed is formed by photolithography. After that, the inactive region is formed by implanting Ar ions into the nitride semiconductor layer in the region where the resist pattern is not formed. The inactive region may be formed by removing a portion of the nitride semiconductor layer in the region where the resist pattern is not formed by dry etching such as reactive ion etching (RIE) using a chlorine-based gas. After the element isolation region is formed, the resist pattern is removed by an organic solvent or the like.

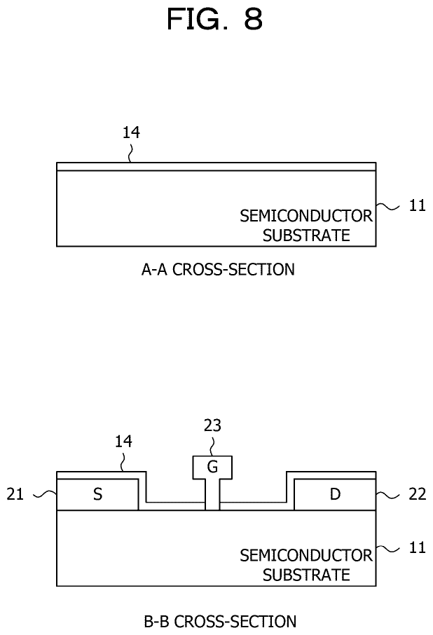

Next, the source electrode 21 and the drain electrode 22 are formed. For example, a resist pattern including openings in regions where the source electrode 21 and the drain electrode 22 are to be formed is formed by photolithography. By using this resist pattern, metals are deposited by the vacuum deposition method. At this time, for example, a metallic laminated film including a Ti film of 2 to 50 nm as the first layer and an Al film of 100 to 300 nm as the second layer is formed. After that, metals other than the source electrode 21 and the drain electrode 22 are removed by the lift-off technique. By performing heat treatment (alloying treatment) at 500 to 650° C. in a nitrogen atmosphere, ohmic contact between the source electrode 21 and the drain electrode 22 is established. With this, as illustrated in FIG. 8, the source electrode 21 and the drain electrode 22 are formed.

The surface protection film 14 is formed over the electron supply layer 11e by plasma CVD. For example, the surface protection film 14 is formed of SiN. The film thickness of the surface protection film 14 is 2 to 100 nm. For example, the surface protection film is formed with a thickness of 50 nm.

The gate electrode 23 is formed. For example, a resist pattern including an opening in a region where the gate electrode 23 is to be formed is formed. By using this resist pattern, metals are deposited by the vacuum deposition method. At this time, for example, a metallic laminated film including an Ni film of 5 to 30 nm as the first layer and an Au film of 100 to 300 nm as the second layer is formed. After that, metals other than the gate electrode 23 is removed by lift-off.

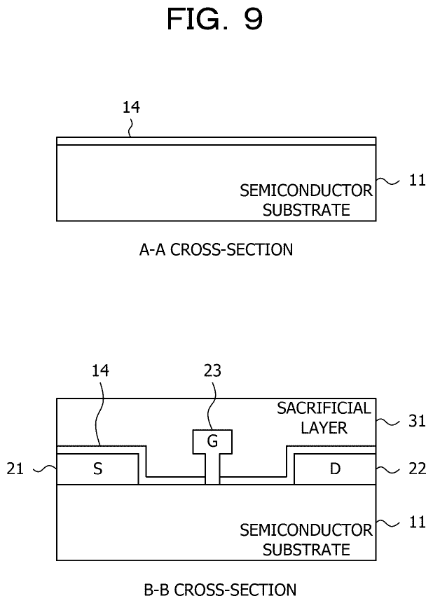

As illustrated in FIG. 9, a sacrificial layer 31 is applied in order to protect the transistor region 20 from the subsequent processes. For example, the sacrificial layer 31 is poly-methylglutarimide (PMGI). The sacrificial layer 31 other than the transistor region 20 is removed.

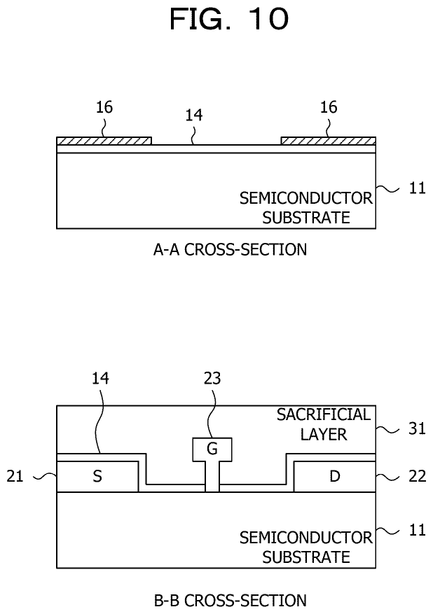

As illustrated in FIG. 10, the resistive film 16 is formed. For example, a resist pattern including an opening in a region where the resistive film 16 is to be formed is formed by photolithography. By using this resist pattern, the resistive film 16 is formed by the sputtering method or the like. For example, the resistive film 16 is formed of nickel chromium (NiCr), titanium nitride (TiN), tantalum nitride (TaN), or the like. After that, resistive film that does not have to be used is removed by the lift-off technique.

When the semiconductor device 2 includes an impedance matching circuit of the amplifier, the resistive film 16 and a resistive element of the impedance matching circuit may be formed in the same process. In this case, the resistive film 16 and the resistive element of impedance matching circuit are formed of the same material and with the same thickness. The sheet resistance of the resistive film 16 is preferably 10 ohms/square or larger. Therefore, the sheet resistance of the resistive film 16 and the resistive element of impedance matching circuit may be 50 ohms/square. The resistive film 16 and the resistive element of impedance matching circuit may be formed in different processes. In this case, the resistive film 16 and the resistive element of impedance matching circuit may be formed by repeating substantially the same process. The resistive film 16 and the resistive element of impedance matching circuit may be formed of different materials or with different sheet resistances.

The semiconductor device 2 may include a capacitive element (not illustrated). For example, the method of forming the capacitive element includes a process of forming one electrode by vapor deposition and lift-off, a process of forming an insulating film by the plasma CVD method, and a process of forming the other electrode by vapor deposition and lift-off.

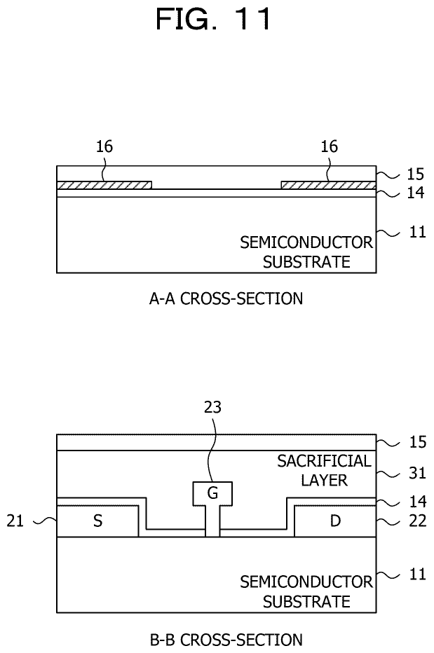

As illustrated in FIG. 11, the interlayer insulating film 15 is formed. For example, the interlayer insulating film 15 is formed by plasma CVD. The interlayer insulating film 15 is formed using SiN or a low dielectric constant material (for example, benzocyclobutene (BCB)).

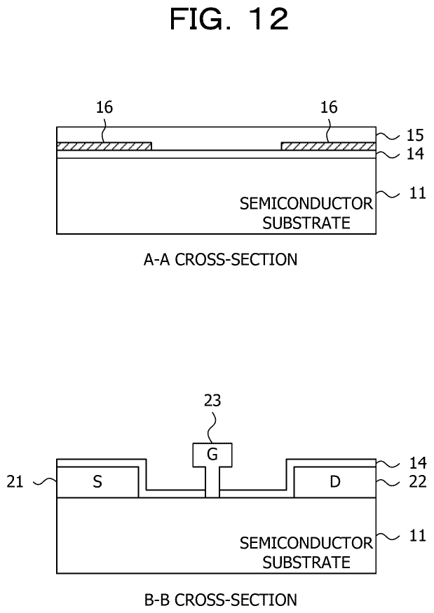

As illustrated in FIG. 12, the interlayer insulating film 15 and the sacrificial layer 31 are removed in the transistor region 20. For example, a resist pattern including an opening in the transistor region 20 is formed by photolithography. By using this resist pattern, the interlayer insulating film 15 in the opening portion is removed by fluorine-based plasma etching. The resist and the sacrificial layer 31 are removed. In the case where the sacrificial layer 31 is formed using PMGI, the sacrificial layer 31 may be removed by using N-methyl-2-pyrrolidone (NMP).

After that, a metal pattern (the signal line 12 and the ground metal 13, or the like) is formed. For example, the interlayer insulating film 15 and the surface protection film 14 in a region to be in contact with the metal pattern (the source electrode 21 and the drain electrode 22, or the like) are removed by fluorine-based dry etching or the like. Subsequently, a sacrificial layer for providing an air bridge is formed, and then a seed metal is formed by sputtering. For example, Ti, Au, or Cu may be used as the seed metal. A resist pattern including an opening in a region where the metal pattern is to be formed is formed. By using this resist pattern, a metal film (Au, Cu, or the like) is formed in the resist opening portion by plating. After that, the resist is peeled off, the seed metal exposed by milling is removed, and the sacrificial layer for air bridge formation is removed by UV or the like, whereby the signal line 12 and the ground metal 13 are formed. By the above-described processes, the semiconductor device 2 illustrated in FIGS. 5 and 6 is obtained.

### Second Exemplary Embodiment

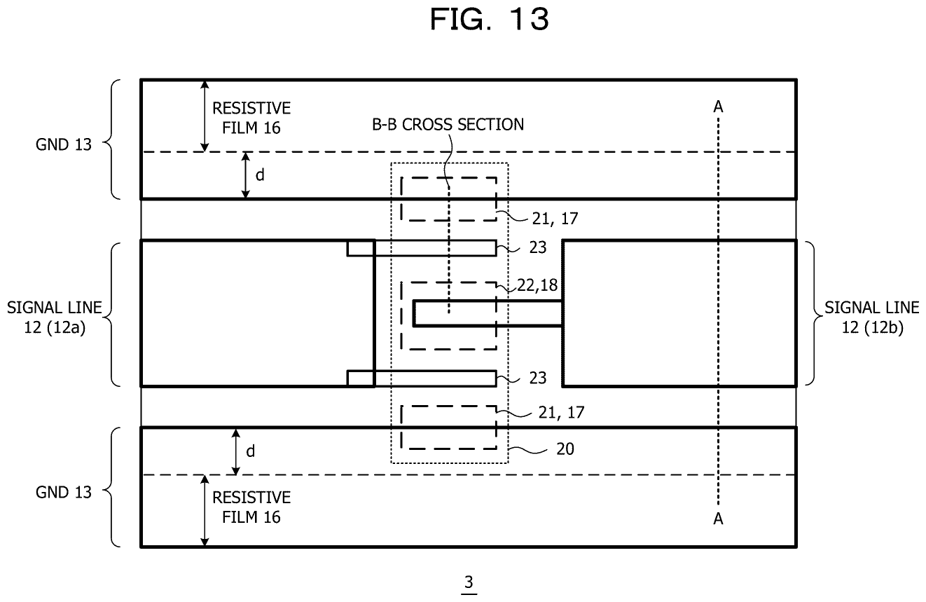

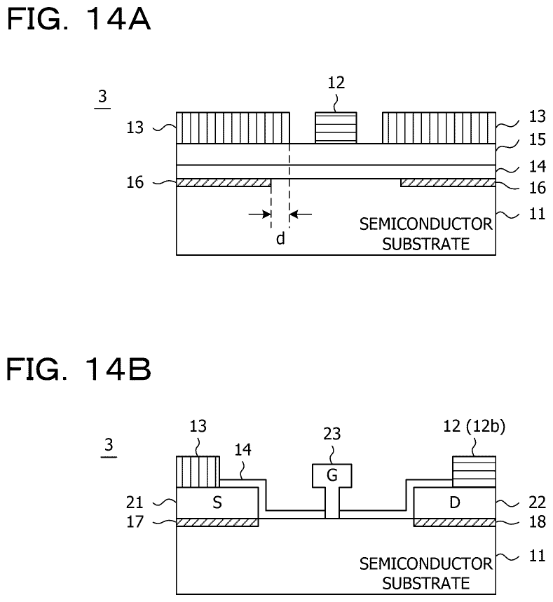

FIG. 13 and FIG. 14 (i.e., FIGS. 14A and 14B) illustrate a configuration of a semiconductor device 3 according to a second exemplary embodiment. FIG. 13 is a top view (plan view) of the semiconductor device 3 according to the second exemplary embodiment. FIG. 14A is a cross-sectional view taken along line A-A of the semiconductor device 3 illustrated in FIG. 13. FIG. 14B is a cross-sectional view taken along line B-B of the semiconductor device 3 illustrated in FIG. 13. As with the semiconductor device 2 according to the first exemplary embodiment, the semiconductor device 3 includes a transistor that operates as an amplifier and a coplanar type line that is coupled to the amplifier. In FIG. 13, the transistor region 20 represents a region where the transistor that operates as an amplifier is formed.

As illustrated in FIG. 13 or FIG. 14B, the transistor includes the source electrode 21, the drain electrode 22, and the gate electrode 23. The coplanar type line is configured by the signal line 12 (12a, 12b) and the ground metal 13.

The source electrode 21 is in contact with the ground metal 13. At least a portion of the lower surface of the source electrode 21 is in contact with a resistive film 17. The resistive film 17 is in contact with the semiconductor substrate 11. For example, the ground metal 13 is electrically coupled to the semiconductor substrate 11 through the source electrode 21 and the resistive film 17. The drain electrode 22 is in contact with the signal line 12 (12b). At least a portion of the lower surface of the drain electrode 22 is in contact with a resistive film 18. The resistive film 18 is in contact with the semiconductor substrate 11. For example, the signal line 12b is electrically coupled to the semiconductor substrate 11 through the drain electrode 22 and the resistive film 18. The resistive films 17 and 18 may reduce the contact resistance between the source electrode 21/drain electrode 22 and the channel of the semiconductor substrate 11. The gate electrode 23 is substantially the same in the first exemplary embodiment and the second exemplary embodiment.

The coplanar type line is substantially the same in the first exemplary embodiment and the second exemplary embodiment. For example, as illustrated in FIG. 14A, a metal film (the signal line 12 and the ground metal 13) constituting the coplanar type line is formed over the upper surface of the semiconductor substrate 11. The resistive film 16 is formed directly under the ground metal 13. However, in the second exemplary embodiment, the resistive film 16 is embedded in the surface region of the semiconductor substrate 11. The surface protection film 14 and the interlayer insulating film 15 are formed between the ground metal 13 and the resistive film 16.

As with the first exemplary embodiment, the resistive film 16 is not formed in a region up to the distance d from the edge of the ground metal 13 on the side facing the signal line 12. The distance d is preferably 10 μm or longer. The resistive film 16 is insulated from the signal line 12 and the ground metal 13 in terms of direct current by the surface protection film 14 and the interlayer insulating film 15. The sheet resistance of the resistive film 16 is preferably 10 ohms/square or larger. The resistive films 16, 17, and 18 may be formed in the same process.

As with the first exemplary embodiment, also in the semiconductor device 3, a radio wave in the semiconductor substrate 11 resulting from an input signal and/or an output signal is attenuated by the resistive film 16. Therefore, even when the thickness of the semiconductor substrate 11 is made larger than ¼ wavelength of the radio wave, radio wave propagation in the substrate is reduced. As a result, unstable behavior is reduced even in the sub-terahertz region. In addition, since the thickness of the semiconductor substrate 11 may be increased, heat dissipation characteristics are improved.

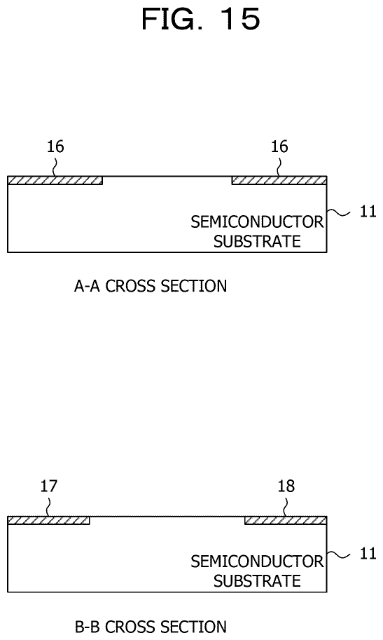

FIGS. 15 to 19 illustrate an example of a method for manufacturing the semiconductor device 3 according to the second exemplary embodiment. The method of forming the initial layer 11b, the electron transit layer 11c, the spacer layer 11d, and the electron supply layer 11e over the substrate 11a is substantially the same in the first exemplary embodiment and the second exemplary embodiment.

As illustrated in FIG. 15, the resistive films 16 to 18 are formed. For example, an insulating film (for example, SiN) is formed over the surface of the semiconductor substrate 11 by the plasma CVD method. A resist pattern including openings in regions where the resistive films 16 to 18 are to be formed is formed by photolithography. The insulating film (for example, SiN) is removed in the opening portions of the resist pattern by dry etching such as RIE using a fluorine-based gas. A portion of the electron transit layer 11c, the spacer layer 11d, and the electron supply layer 11e is removed in the opening portions of the resist pattern by dry etching such as RIE using a chlorine-based gas. After that, the resist is removed.

The resistive films 16 to 18 are formed with the same material as the semiconductor that forms the electron transit layer 11c by MOCVD or molecular beam epitaxy (MBE). Alternatively, the resistive films 16 to 18 may be formed such that the main components (for example, 50% or more of the constituent components) of the resistive films 16 to 18 are the same as the semiconductor that forms the electron transit layer 11c. For example, in the case of a GaN-based semiconductor, GaN films exhibiting an n-type conductivity type are formed as the resistive films 16 to 18 by using an impurity such as Si or Ge. After that, the insulating film is removed by wet etching using hydrofluoric acid (HF) or the like.

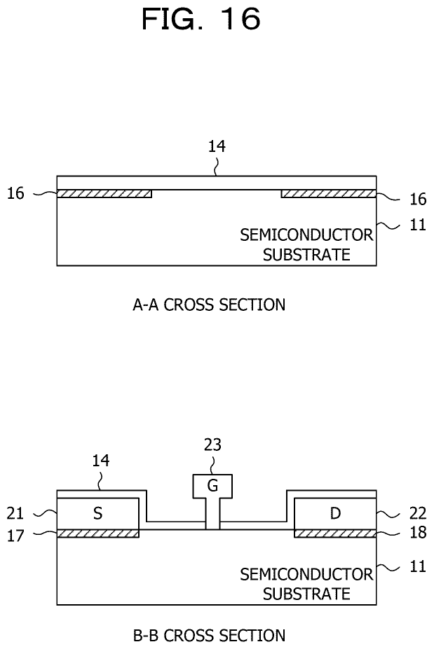

As illustrated in FIG. 16, the source electrode 21, the drain electrode 22, the surface protection film 14, and the gate electrode 23 are formed. The method of forming the source electrode 21, the drain electrode 22, the surface protection film 14, and the gate electrode 23 is substantially the same in the first exemplary embodiment and the second exemplary embodiment.

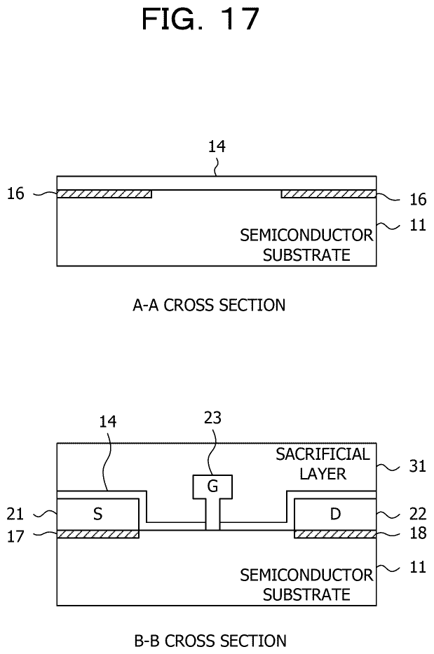

As illustrated in FIG. 17, the sacrificial layer 31 is applied in order to protect the transistor region 20 from the subsequent processes. For example, the sacrificial layer 31 is PMGI. The sacrificial layer 31 other than the transistor region 20 is removed.

The semiconductor device 3 may include an impedance matching circuit of the amplifier. For example, the impedance matching circuit is realized by a resistive element. In this case, a resist pattern including an opening in a region where the resistive element is to be formed is formed by photolithography. By using this resist pattern, the resistive element is formed by the sputtering method or the like. For example, the resistive element is formed of NiCr, TiN, TaN, or the like. After that, resistive film that does not have to be used is removed by the lift-off technique.

The semiconductor device 3 may include a capacitive element (not illustrated). For example, the method of forming the capacitive element includes a process of forming one electrode by vapor deposition and lift-off, a process of forming an insulating film by the plasma CVD method, and a process of forming the other electrode by vapor deposition and lift-off.

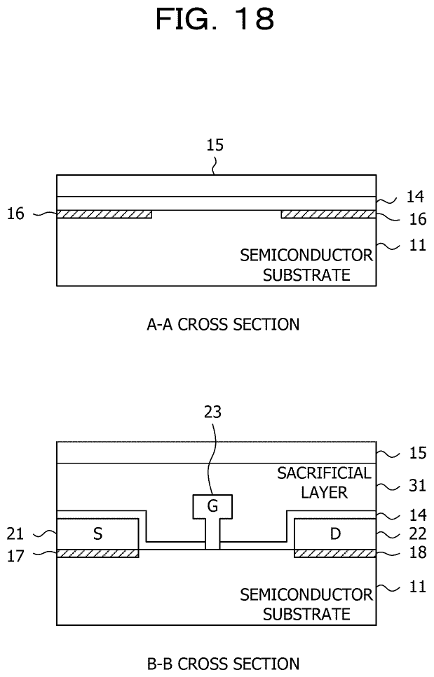

As illustrated in FIG. 18, the interlayer insulating film 15 is formed. For example, the interlayer insulating film 15 is formed by plasma CVD. The interlayer insulating film 15 is formed using SiN or a low dielectric constant material (for example, benzocyclobutene (BCB)).

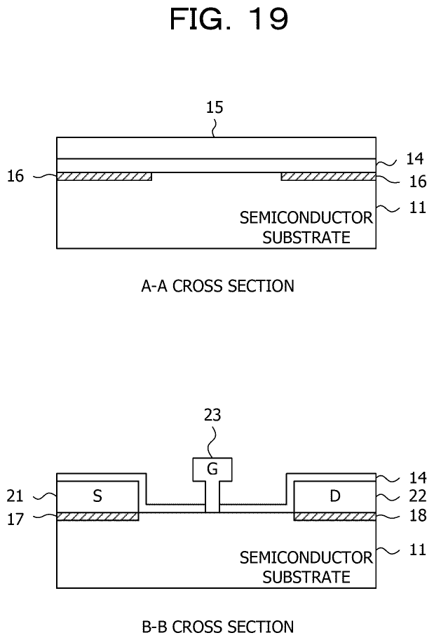

As illustrated in FIG. 19, the interlayer insulating film 15 and the sacrificial layer 31 are removed in the transistor region 20. The method of removing the interlayer insulating film 15 and the sacrificial layer 31 in the transistor region 20 is substantially the same in the first exemplary embodiment and the second exemplary embodiment.

After that, a metal pattern (the signal line 12 and the ground metal 13, or the like) is formed. The method of forming a metal pattern on a substrate is substantially the same in the first exemplary embodiment and the second exemplary embodiment. By the above-described processes, the semiconductor device 3 illustrated in FIGS. 13 and 14 is obtained.

### Application Example

The semiconductor devices 2 and 3 according to the embodiment of the present disclosure may be used as amplifiers capable of amplifying a signal in the sub-terahertz band. Therefore, for example, the semiconductor devices 2 and 3 may be used in a wireless device of a next-generation communication system.

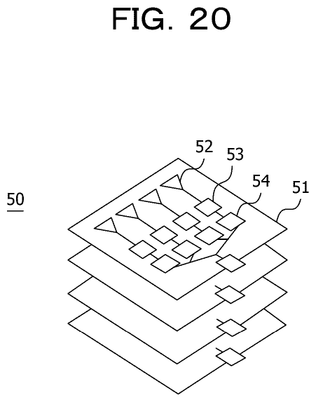

FIG. 20 illustrates an example of communication equipment in which the semiconductor device according to the embodiment of the present disclosure is mounted. In this example, communication equipment 50 includes four antenna modules 51. Each antenna module 51 includes four sets of antenna circuits. For example, the communication equipment 50 is a 4×4 array antenna module. Each antenna circuit includes an antenna 52, an amplifier 53, and a phase shifter/mixer 54. The amplifier 53 is realized by the semiconductor device 2 or the semiconductor device 3 described above.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a semiconductor substrate;
a coplanar type line that includes a signal line and a ground metal formed on a surface side of the semiconductor substrate; and
a first resistive film formed between a surface of the semiconductor substrate and the ground metal or between a surface of the semiconductor substrate and a region where there is no metal over the semiconductor substrate,
wherein the ground metal and the first resistive film are insulated from each other.

2. The semiconductor device according to claim 1, wherein
the first resistive film is formed between a surface of the semiconductor substrate and the ground metal such that an edge of the first resistive film does not reach an edge of the ground metal on a side that faces the signal line.

3. The semiconductor device according to claim 2, wherein
a distance between an edge of the first resistive film and an edge of the ground metal on a side that faces the signal line is 10 μm or longer.

4. The semiconductor device according to claim 1, wherein
sheet resistance of the first resistive film is 10 ohms/square or larger.

5. The semiconductor device according to claim 1, wherein
in a configuration in which the first resistive film is formed between a surface of the semiconductor substrate and the ground metal, an insulating film is formed between the first resistive film and the ground metal.

6. The semiconductor device according to claim 1, wherein
a source electrode formed over an upper surface of the semiconductor substrate,
a drain electrode formed over an upper surface of the semiconductor substrate, and
a gate electrode formed over an upper surface of the semiconductor substrate in a region between the source electrode and the drain electrode, are further included,
the signal line includes a first signal line and a second signal line,
the ground metal is electrically coupled to the source electrode,
the first signal line is electrically coupled to the gate electrode, and
the second signal line is electrically coupled to the drain electrode.

7. The semiconductor device according to claim 6, wherein
a second resistive film formed over the semiconductor substrate and in contact with the source electrode, and
a third resistive film formed over the semiconductor substrate and in contact with the drain electrode, are further included.

8. The semiconductor device according to claim 7, wherein
the first resistive film, the second resistive film, and the third resistive film are formed with a same material as an electron transit layer formed on a surface of the semiconductor substrate.

9. The semiconductor device according to claim 7, wherein
components of 50% or more of materials for formation of the first resistive film, the second resistive film, and the third resistive film are same as those of an electron transit layer formed on a surface of the semiconductor substrate.

10. The semiconductor device according to claim 1, wherein
an amplifier electrically coupled to the coplanar type line over the semiconductor substrate and
a resistive element of an impedance matching circuit of the amplifier, which is electrically coupled to the signal line, are further included, and
the first resistive film and the resistive element are formed in a same process.
